(19) United States
(12) Patent Application Publication
(10) Pub. No.: US 2025/0076372 A1
(43) Pub. Date: Mar. 6, 2025

(54) INSPECTION METHOD AND INSPECTION APPARATUS

(71) Applicant: Tokyo Electron Limited, Tokyo (JP)

(72) Inventor: Sooraj RAJENDRAN, Yamanashi (JP)

(21) Appl. No.: 18/808,265

(22) Filed: Aug. 19, 2024

(30) Foreign Application Priority Data
Aug. 30, 2023 (JP) 2023-139484

(51) Int. Cl. G01R 31/28; G01R 1/073

(52) U.S. Cl. CPC G01R 31/2891; G01R 1/07342

(57) ABSTRACT

An adjustment method is provided for an inspection apparatus configured to inspect an inspection object by bringing a tip of a probe disposed on a probe card into contact with an electrode disposed on the inspection object. The method includes projecting, by a projector, an optical dot pattern in which optical dots are arranged, receiving the optical dots by a light receiver, capturing a standard image including the optical dots projected by the projector, capturing a measurement image including at least two of the optical dots of the optical dot pattern received by the light receiver, and adjusting a stage on which the inspection object is disposed, according to the standard image and the measurement image.

### CROSS-REFERENCE TO RELATED APPLICATIONS

The present application is based on and claims priority to Japanese patent application No. 2023-139484, filed on Aug. 30, 2023 with the Japanese Patent Office, the entire contents of which are hereby incorporated by reference.

### TECHNICAL FIELD

The disclosures herein relate to an inspection method and an inspection apparatus.

### BACKGROUND

For example, an inspection of an electric characteristic of a semiconductor device is performed using an inspection apparatus, as a semiconductor wafer before dividing into each semiconductor device. The inspection apparatus has a probe card on which probes are disposed. The inspection apparatus inspects the semiconductor device by bringing a tip of the probe disposed on the probe card into contact with a test pad (electrode) disposed on the semiconductor device, supplying electric signals to the semiconductor device through the probe, and acquiring electric signals outputted from the semiconductor device through the probe. In order to bring the probe tips disposed on the probe card into test pad disposed on the contact with the semiconductor device, it is required to adjust a relative positional relationship between the needle tip of the probe and the test pad correctly.

For example, the Patent Literature (PTL) 1 discloses an inspection apparatus, which specifies a position of the tip of each probe needle in the image captured by a camera, and adjusts the position of the tip of each probe needle on the basis of the specified position of the tip of each probe needle.

### CITATION LIST

### Patent Literature

[PTL1] Japanese Laid-Open Patent Publication No. 2019-102640

### SUMMARY OF THE INVENTION

An adjustment method for an inspection apparatus configured to inspect an inspection object by bringing a tip of a probe disposed on a probe card into contact with an electrode disposed on the inspection object, including:
projecting, by a projector, an optical dot pattern in which optical dots are arranged;
receiving the optical dots by a light receiver;
capturing a standard image including the optical dots projected by the projector;
capturing a measurement image including at least two of the optical dots of the optical dot pattern received by the light receiver; and
adjusting a stage on which the inspection object is disposed, according to the standard image and the measurement image.

### BRIEF DESCRIPTION OF THE DRAWINGS

FIG. 1 is an outline cross section illustrating one example of an inspection apparatus;

FIG. 2 is an outline cross section illustrating one example of a probe camera unit;

FIG. 3 is an outline cross section illustrating one example of a wafer camera unit;

FIG. 4 is a block diagram illustrating one example of a computer hardware structure;

FIG. 5 is a block diagram illustrating one example of a controller function structure;

FIG. 6 is a drawing illustrating one example of a standard image;

FIG. 7 is a drawing illustrating one example of a measurement image;

FIG. 8 is a drawing illustrating one example of a position difference detecting method;

FIG. 9 is a drawing illustrating one example of a relationship between a working distance and an optical dot pattern;

FIG. 10 is a drawing illustrating one example of brightness adjustment according to a working distance;

FIG. 11 is a drawing illustrating one example of a relationship between an optical axis difference and an optical dot pattern;

FIG. 12 is a drawing illustrating one example of distortion compensation;

FIG. 13 is a flow chart illustrating one example of the inspection method;

FIG. 14 is a flow chart illustrating one example of a stage adjusting process;

FIG. 15 is a schematic diagram illustrating one example of a condition of an inspection apparatus;

FIG. 16 is a schematic diagram illustrating one example of a condition of an inspection apparatus;

FIG. 17 is a schematic diagram illustrating one example of a condition of an inspection apparatus;

FIG. 18 is a schematic diagram illustrating one example of a condition of an inspection apparatus;

FIG. 19 is a schematic diagram illustrating one example of a condition of an inspection apparatus; and

FIG. 20 is a schematic diagram illustrating one example of a condition of an inspection apparatus.

### DETAILED DESCRIPTION

In the following, embodiments of the present invention will be described with reference to the accompanying drawings.

### Embodiments

One embodiment of the present disclosure is an inspection apparatus which inspects a semiconductor device, one example of an inspection object. In the present embodiment, the inspection apparatus inspects an electric characteristic of the semiconductor device formed on a semiconductor wafer, by bringing a tip of a probe disposed on a probe card into contact with a test pad disposed on the semiconductor wafer.

In the inspection apparatus, as preheating and inspection are performed at a high temperature, a minute vibration occurs at the semiconductor wafer and the probe card by thermal expansion. Moreover, even if the relative positional relationship between the probe tips and the test pad has been adjusted beforehand, as a stage where the semiconductor wafer is disposed is moved to bring the probe tips into contact with the test pad, a deviation may ultimately occur with respect to the position of the probe tips and the position of the test pad.

The inspection apparatus disclosed in the present embodiment includes two camera units which are movable to a facing position in order to bring the probe tips into contact with the test pad accurately. A first camera unit projects optical dot patterns including optical dots to a direction of a second camera unit. The second camera unit receives the optical dot patterns projected by the first camera unit.

The inspection apparatus adjusts a position of the stage where the semiconductor wafer is disposed, according to differences between the optical axes projected by the first camera unit, and the optical axes received by the second camera unit (referred to as “optical axis differences” hereinafter). The optical axis differences include a difference of a position in an x-y plane (referred to as a “position difference” hereinafter), and a difference of an inclination to a z-axis (referred to as an “inclination difference” hereinafter). Therefore, the inspection apparatus can control the position in the x-y plane and the inclination to the z-axis of the stage according to the optical axis differences.

The inspection apparatus can detect accurately both the position difference and the inclination difference by using an optical dot pattern including optical dots. From one aspect, the inspection apparatus of the present embodiment can bring the needle tip of the probe into contact with the electrode of the inspection object accurately.

### <Inspection Apparatus>

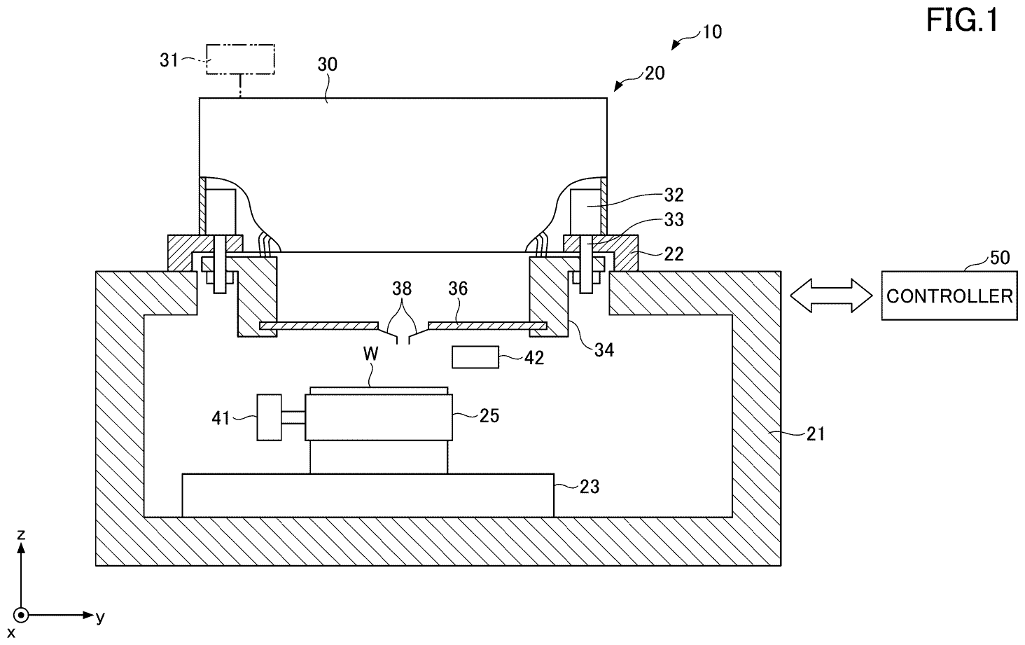

One example of the inspection apparatus of the present embodiment is described referring to FIG. 1. FIG. 1 is an outline cross section illustrating one example of an inspection apparatus of the embodiment.

As shown in FIG. 1, the inspection apparatus 10 has an inspection apparatus main body 20 and the controller 50. The inspection apparatus main body 20 has an empty enclosure 21. Approximately at a center of the enclosure 21, an actuator 23 to move the stage 25 in a vertical direction (a direction of a z-axis shown in FIG. 1) and a horizontal direction (a direction parallel to an x-axis and a y-axis in an x-y plane shown in FIG. 1) is disposed. On an upper surface of the stage 25, a semiconductor wafer (referred to as a wafer W hereinafter), which is one example of an inspection object, is disposed. The stage 25 supports the wafer W disposed on its upper surface by adsorbing with a vacuum chuck and the like.

On a lateral face of the stage 25, a probe camera unit 41 (also referred to as “PCU” hereinafter) is disposed. The probe camera unit 41 can move to the position facing a probe card 36 or a wafer camera unit 42, mentioned below. For example, when the actuator 23 moves the stage 25, the probe camera unit 41 disposed on the lateral face of the stage 25 moves. The actuator 23 is controlled by the controller 50. An amount of movement of the actuator 23 is operated by the controller 50. A position of the probe camera unit 41 within the enclosure 21 is controlled by the controller 50.

The probe camera unit 41 projects an optical dot pattern where optical dots are arranged to a predetermined direction. The probe camera unit 41 is disposed to project the optical dot pattern upward. The probe camera unit 41 captures an image including the projected optical dot pattern (also referred to as a “standard image” hereinafter).

Within the enclosure 21, a wafer camera unit 42 (also referred to as “WCU” hereinafter) is disposed. The wafer camera unit 42 can move to the position facing the stage 25 or the probe camera unit 41. A position of the wafer camera unit 42 within the enclosure 21 is controlled by the controller 50.

The wafer camera unit 42 receives the optical dot pattern projected by the probe camera unit 41. The wafer camera unit 42 is disposed to face the probe camera unit 41 in the enclosure 21, and to receive the optical dot pattern projected from below. The wafer camera unit 42 captures images including a part of the received optical dot pattern (also referred to as “measurement images” hereinafter).

The enclosure 21 has an approximately circular opening on the top. A test head 30 is disposed over the opening of the enclosure 21. The test head 30 is fixed to a frame 22 disposed along a circumferential edge of the opening. At the position of the frame 22 within the test head 30, inclination adjusters 32 are disposed. The inclination adjusters 32 are disposed around the opening at regular intervals along the frame 22. The inclination adjusters 32 support an approximately circular holder 34, from an upper part through a shaft 33, at a lower part of the frame 22.

The holder 34 supports removably a probe card 36, where probes 38 are disposed, from a lower part. The probes 38 disposed on the probe card 36 are disposed with their needle tips downward. The probe card 36 shown in FIG. 1 is an example of cantilever type probes 38, but the probe may be in another shape, for example a vertical type.

On the probe card 36, the probes 38 are disposed in order for the needle probe tips 38 to come in contact with the test pad disposed on the wafer W, when the wafer W disposed on the stage 25 moves to the position of inspection. The probes 38 are connected to a circuit on the probe card 36. The circuit disposed on the probe card 36 is connected to the test head 30 through a circuit disposed on the holder 34. An external tester 31 is connected to the test head 30.

When the wafer W disposed on the stage 25 is inspected, the controller 50 moves the probe camera unit 41 and the wafer camera unit 42 to a position where they face each other. The controller 50 adjusts the position of the stage 25, according to the standard image captured by the probe camera unit 41, and the measurement images captured by the wafer camera unit 42. Specifically, the controller 50 controls the position of the stage 25 in the x-y plane, and the inclination of the stage 25 to the z-axis, by the actuator 23 in order for the needle probe tips 38 to face each test pad on the wafer W disposed on the stage 25.

The controller 50 brings the needle probe tips 38 into contact with each test pad on the wafer W by raising the stage 25 after adjusting the position of the stage 25. Subsequently, the controller 50 controls the external tester 31 to output a predetermined electric signal to the test head 30. The test head 30 outputs the electric signal outputted from the external tester 31 to the probe card 36 through the circuit on the holder 34. The electric signal outputted to the probe card 36 is supplied to the probes 38 through the circuit on the probe card 36. The electric signal supplied to the probes 38 is outputted to the test pad on the wafer W through the probes 38.

The electric signal outputted from the test pad on the wafer W is outputted to the probe 38. The electric signal outputted to the probes 38 is outputted to the test head 30 through the circuit on the probe card 36 and the circuit on the holder 34. The electric signal outputted to the test head 30 is outputted to the external tester 31.

The external tester 31 evaluates electrical characteristics of the wafer W, according to the electric signal outputted to the test head 30 and the electric signal outputted from the test head 30, and outputs a result of evaluation to the controller 50.

### <Probe Camera Unit>

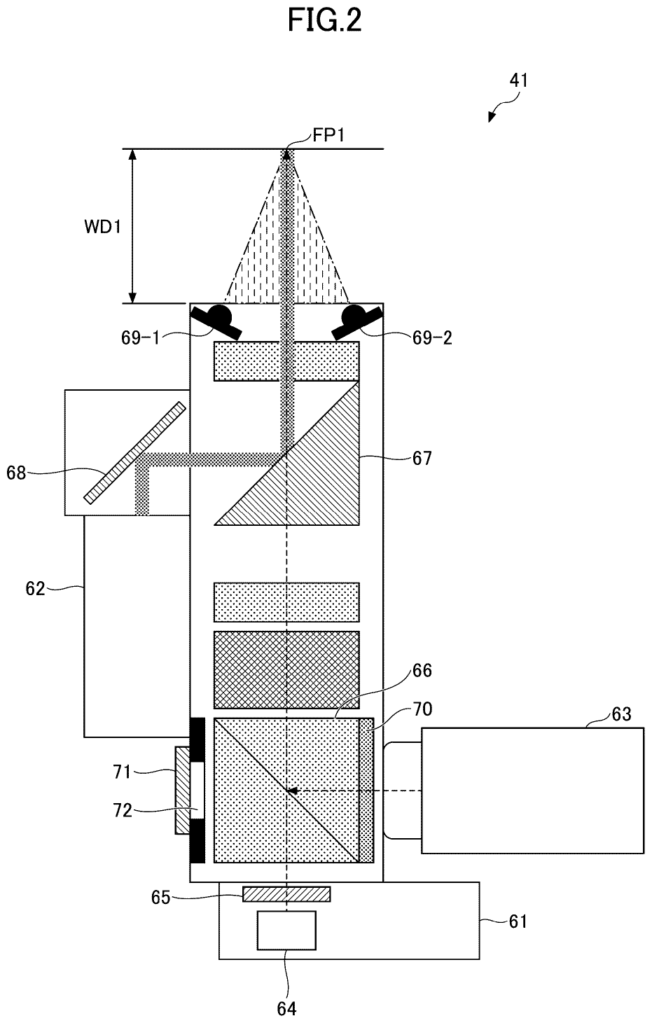

One example of a probe camera unit of the present embodiment is described referring to FIG. 2. FIG. 2 is an outline cross section illustrating one example of a probe camera unit of the present embodiment.

As shown in FIG. 2, the probe camera unit 41 includes a projector 61, an illuminator 62, and a camera 63 (one example of a first camera).

The projector 61 includes a monochromatic light source 64 and a diffractive optical element 65. The monochromatic light source 64 irradiates a strong monochromatic light. A wavelength of the strong monochromatic light may optionally be configured. The diffractive optical element 65 forms a light source pattern including light sources by diffracting the strong monochromatic light irradiated from the monochromatic light source 64. An optical dot pattern formed by the diffractive optical element 65 is projected upward through a prism 66 and a half mirror 67.

The illuminator 62 is a bright field illumination irradiating a visible light. The visible light irradiated from the illuminator 62 is irradiated upward via a mirror 68 and the half mirror 67. The visible light irradiated from the illuminator 62 joins the strong monochromatic light irradiated from the monochromatic light source 64 at the half mirror 67.

The optical dot pattern irradiated from the probe camera unit 41 becomes observable at a focal point FP1 by irradiation of dark field illuminations 69-1, 69-2. Moreover, a working distance WD1 is a distance between the probe camera unit 41 and the focal point FP1.

The camera 63 captures a standard image including the optical dot pattern formed by the diffractive optical element 65. In the present embodiment, the camera 63 captures the standard image including an entire optical dot pattern. The strong monochromatic light irradiated from the monochromatic light source 64 is diverged through the prism 66 to a direction intersecting a direction of the irradiation of the strong monochromatic light. A filter wheel 70 is disposed in the direction of the camera 63 from the prism 66, and in an opposite direction, a mirror 71 and an optical shutter 72 are disposed.

The camera 63 captures the optical dot pattern reflected by the mirror 71, using the filter wheel 70 and the optical shutter 72. When the optical shutter 72 is open, the camera 63 can capture the optical dot pattern, and when the optical shutter 72 is closed, it can capture a visual field above the probe camera unit 41.

### <Wafer Camera Unit>

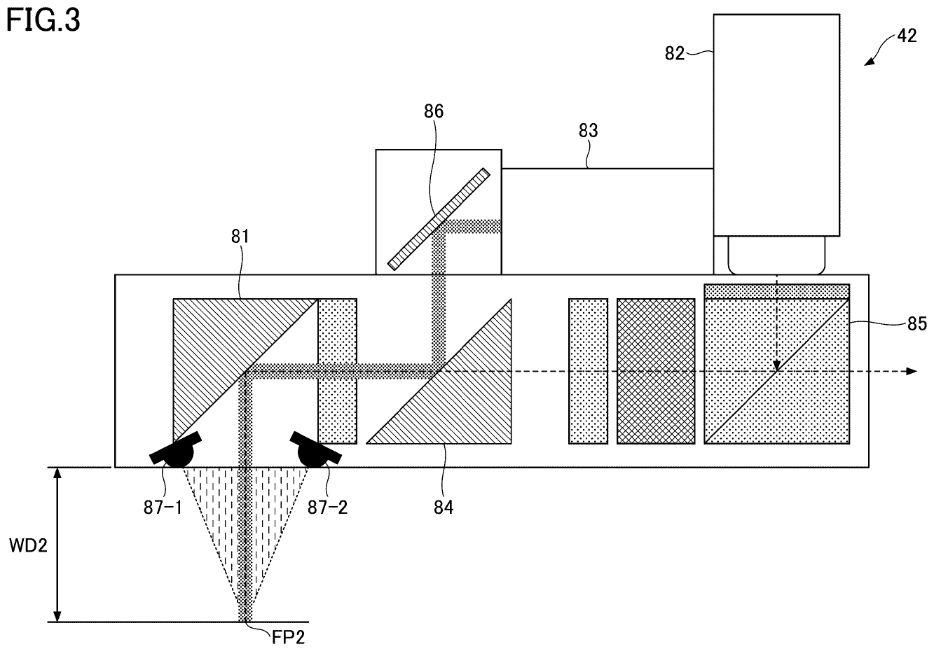

One example of a wafer camera unit of the present embodiment is described referring to FIG. 3. FIG. 3 is an outline cross section illustrating one example of the wafer camera unit of the present embodiment.

As shown in FIG. 3, the wafer camera unit 42 includes a light receiver 81, a camera 82 (one example of a second camera), a bright field illumination 83, and dark field illuminations 87-1, 87-2.

When the probe camera unit 41 and the wafer camera unit 42 are in a positional relationship to face each other, an optical dot pattern irradiated from the probe camera unit 41 is incident on the wafer camera unit 42. The wafer camera unit 42 receives the optical dot pattern incident on the wafer camera unit 42 by the light receiver 81. The light receiver 81 is, for example, a mirror to reflect the optical dot pattern to a capturable direction by the camera 82.

The optical dot pattern received by the light receiver 81 is captured by the camera 82 through a half mirror 84 and a prism 85. Moreover, a working distance WD2 is a distance between the wafer camera unit 42 and a focal point FP2. When the probe camera unit 41 and the wafer camera unit 42 are in a facing positional relationship, and the focal point FP1 shown in FIG. 2 is located at the position corresponding to the focal point FP2 shown in FIG. 3, the camera 82 can capture the optical dot pattern clearly.

The camera 82 captures measurement images including optical dots detected by a wafer camera unit 42 at a predetermined interval. In the present embodiment, the camera 82 captures measurement images including at least two optical dots within axes included in the optical dot pattern. For example, the camera 82 may capture the optical dot pattern with higher magnification than that of the camera 63 of the probe camera unit 41. The magnification may be configured as desired, as long as it is higher than one, for example, it may be two.

In the present embodiment, a focal length of the camera 82 is fixed. Depth of field of the camera 82 is preferably structured larger than depth of field of the camera 63.

The bright field illumination 83 is a bright field illumination where visible light is irradiated. The visible light irradiated in the bright field illumination 83 joins the optical dot pattern received by the light receiver 81 at the half mirror 84 via the mirror 86. The optical dot pattern received by the light receiver 81 becomes observable at a focal point FP2 by irradiation of dark field illuminations 87-1, 87-2.

### <Hardware Structure>

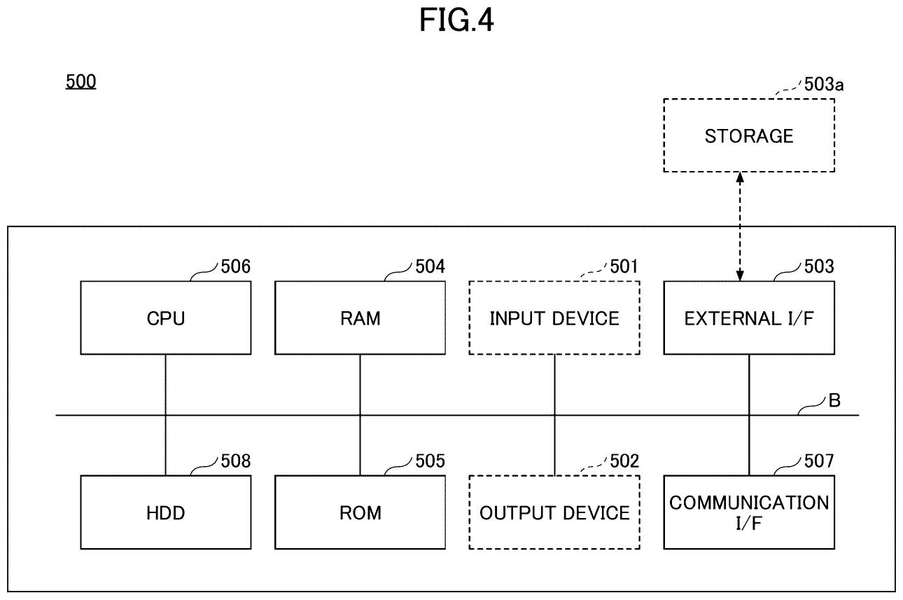

The controller 50 shown in FIG. 1 is achieved for example a computer of a hardware structure by, shown in FIG. 4. FIG. 4 is a block diagram illustrating one example of a computer hardware structure of the present embodiment.

As shown in FIG. 4, a computer 500 includes an input device 501, an output device 502, an external I/F (interface) 503, RAM (Random Access Memory) 504, ROM (Read Only Memory) 505, CPU (Central Processing Unit) 506, a communication I/F 507, HDD (Hard Disk Drive) 508, etc. and they are connected by a bus B mutually. Moreover, the input device 501 and the output device 502 may be of a form to connect to use as needed.

The input devices 501 are a keyboard, a mouse, a touch panel, etc., and used for an operator and the like to input various control signals. The output device 502 is a display and the like, and displays results of processes by the computer 500. The communication I/F 507 is an interface to connect the computer 500 to a network. The HDD 508 is one example of a nonvolatile storage.

The external I/F 503 is an interface with external devices. The computer 500 can read and/or write to a storage 503a such as an SD (Secure Digital) memory card through the external I/F 503. The ROM 505 is one example of a nonvolatile semiconductor memory (storage) to store programs or data. The RAM 504 is one example of a volatile semiconductor memory (storage) to store programs or data temporarily.

The CPU 506 is an arithmetic unit to achieve controls and functions of the entire computer 500 by reading programs or data from storages such as the ROM 505 or the HDD 508 to the RAM 504, and performing processes.

### <Function Structure>

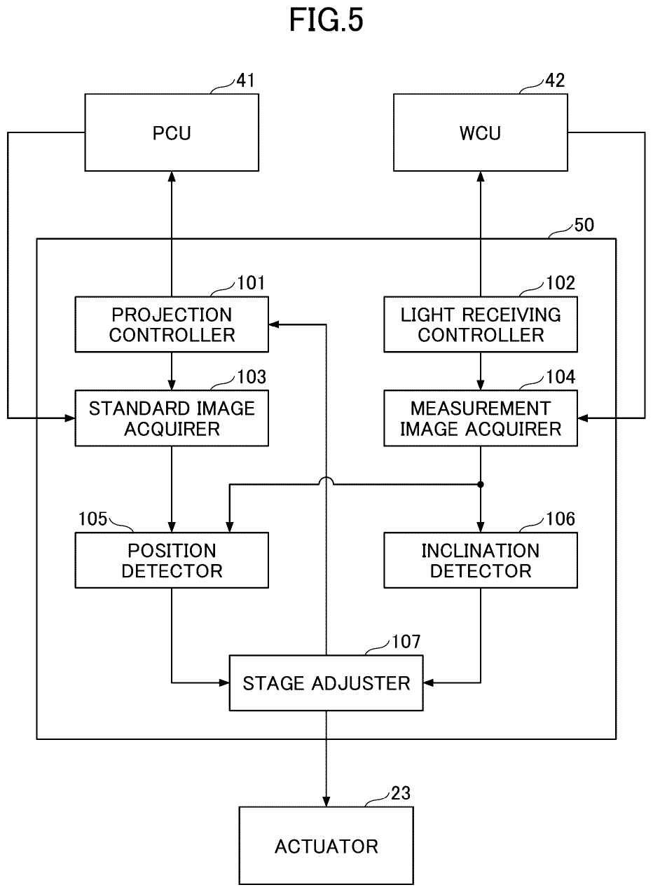

A controller function structure of the present embodiment is described referring to FIG. 5. FIG. 5 is a block diagram illustrating one example of a controller function structure of the present embodiment.

As shown in FIG. 5, the controller 50 of the present embodiment includes a projection controller 101, a light receiving controller 102, a standard image acquirer 103, a measurement image acquirer 104, a position detector 105, an inclination detector 106, and a stage adjuster 107.

The projection controller 101, the light receiving controller 102, the standard image acquirer 103, the measurement image acquirer 104, the position detector 105, the inclination detector 106, and the stage adjuster 107 are achieved, for example, as the CPU 506 shown in FIG. 4 executes a program loaded on the RAM 504.

The projection controller 101 controls the probe camera unit 41 to project the optical dot pattern. The projection controller 101 controls the optical dot pattern projected by the probe camera unit 41 to vary its brightness according to a height of the stage 25.

The light receiving controller 102 controls the wafer camera unit 42 to receive the optical dot pattern projected by the probe camera unit 41. Control of the wafer camera unit 42 to receive the optical dot pattern includes a control of the wafer camera unit 42 to move to a position where the optical dot pattern is receivable.

The standard image acquirer 103 controls the probe camera unit 41 to capture the standard image. The standard image acquirer 103 acquires the standard image captured by the probe camera unit 41.

The measurement image acquirer 104 controls the wafer camera unit 42 to capture the measurement images at a predetermined interval. The measurement image acquirer 104 acquires the measurement images captured by the wafer camera unit 42. When optical distortion occurs in a measurement image, the measurement image acquirer 104 compensates the optical distortion.

The position detector 105 detects a position difference in an x-y plane of the stage 25, according to the standard image acquired by the standard image acquirer 103, and the measurement images acquired by the measurement image acquirer 104. Specifically, the position detector 105 detects a position difference according to a relative position of the measurement images with respect to the standard image.

The inclination detector 106 detects the inclination difference of the stage 25 with respect the according to z-axis measurement images acquired by the measurement image acquirer 104. Specifically, the inclination detector 106 detects inclination difference according to the positional variations of optical dots included in measurement images captured before and after the height of the stage 25 is varied.

The stage adjuster 107 controls the stage 25 by adjustment. The stage adjuster 107 adjusts the position of the stage 25 according to the position difference detected by the position detector 105. The stage adjuster 107 adjusts inclination of the stage 25 according to the inclination difference detected by the inclination detector 106.

The stage adjuster 107 controls the stage 25 to rise in order to bring the needle tips of the probe 38 into contact with each test pad on the wafer W. When the stage adjuster 107 varies the height of the stage 25, it notifies the difference of height to the projection controller 101. The projection controller 101 adjusts the brightness of the optical dot pattern according to the variation of the height.

### <Standard Image>

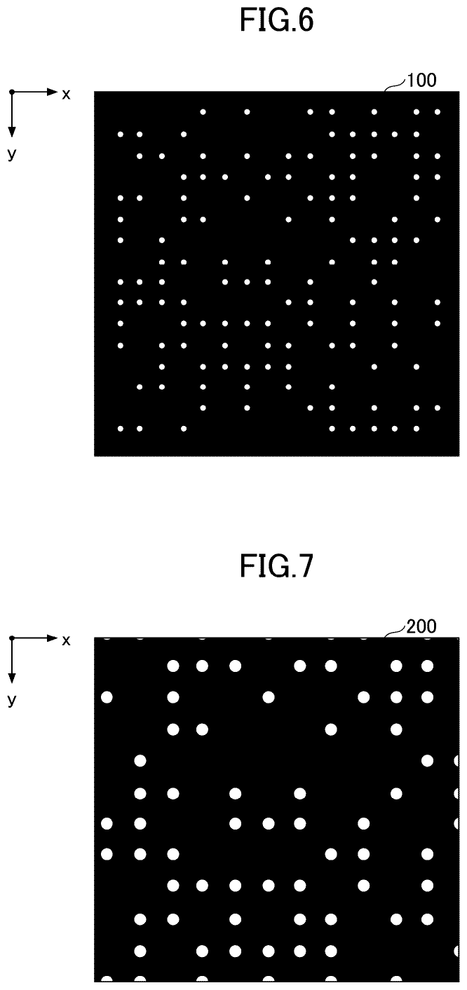

A standard image in the present embodiment is described referring to FIG. 6. FIG. 6 is a drawing illustrating one example of a standard image.

As shown in FIG. 6, optical dots (dots) are captured in the standard image 100. Optical dots are arranged randomly in the standard image 100. In the standard image 100 shown in FIG. 6, for example, optical dots are arranged asymmetrically with respect to the x-axis and the y-axis. Moreover, FIG. 6 illustrates the x-axis and the y-axis in an image coordinate system. Axes with respect to which optical dots are asymmetrical are not limited to an x-axis or a y-axis, and axes may be configured as desired.

### <Measurement Image>

A measurement image in the present embodiment is described referring to FIG. 7. FIG. 7 is a drawing illustrating one example of a measurement image.

The measurement image 200 shown in FIG. 7 is a captured part of the optical dot pattern captured in the standard image 100 shown in FIG. 6. As shown in FIG. 7, in the measurement image 200, a smaller number of optical dots than that of the standard image 100 are captured, and the optical dots are larger than in the standard image 100.

### <Position Difference Detection>

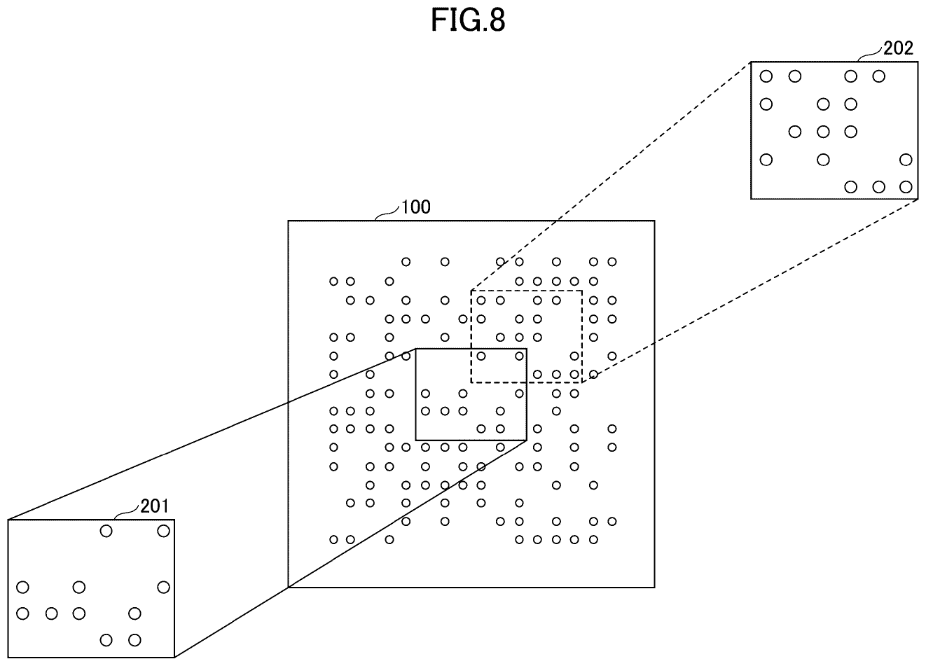

A method to detect a position difference according to the standard image and the measurement images in the present embodiment is described referring to FIG. 8. FIG. 8 is a drawing illustrating one example of a position difference detecting method.

When the probe camera unit 41 and the wafer camera unit 42 are in a position where they are facing, if there is not a position difference, an arrangement of the optical dots captured in the measurement image corresponds to an arrangement of the optical dots near the center of the standard image. Conversely, if there is a position difference, an arrangement of the optical dots captured in the measurement image does not correspond to an arrangement of the optical dots near the center of the standard image. That is, when the arrangement of the optical dots captured in the measurement image does not correspond to the arrangement of the optical dots near the center of the standard image, it is shown that there is a position difference.

As shown in FIG. 8, the measurement image 201 is a measurement image which is a part of the standard image 100 captured near the center. Moreover, the measurement image 202 is a measurement image which is a part of the standard image 100 captured at the upper right to the center. When the measurement image 201 is captured by the wafer camera unit 42, a position difference does not occur. Conversely, when the measurement image 202 is captured by the wafer camera unit 42, a position difference occurs.

The position detector 105 can detect a position difference for example by template matching. Specifically, the position detector 105 estimates a relative position of the measurement image 200 in the standard image 100 by template matching, and detects the distance between the center of the standard image 100 and the estimated relative position as a position difference.

### <Contrast Compensation>

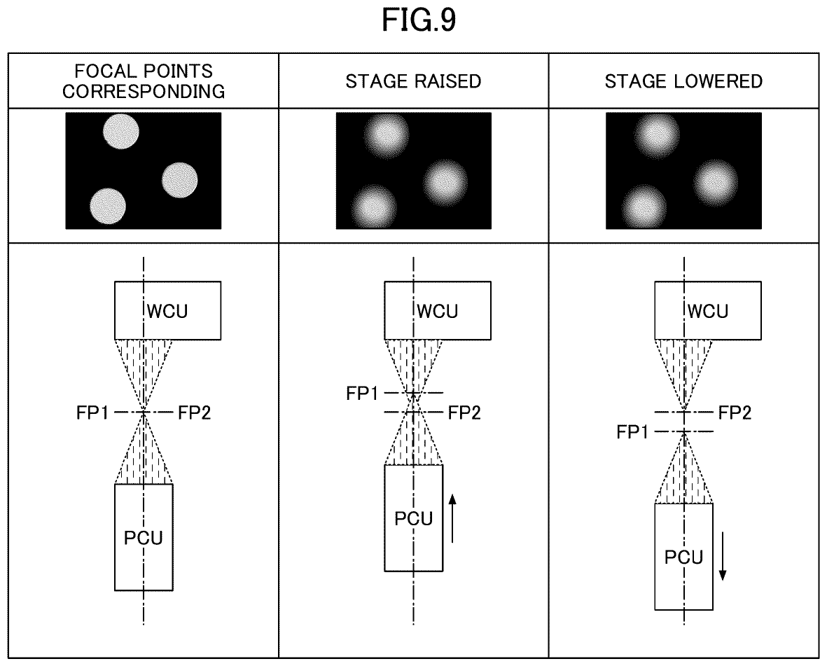

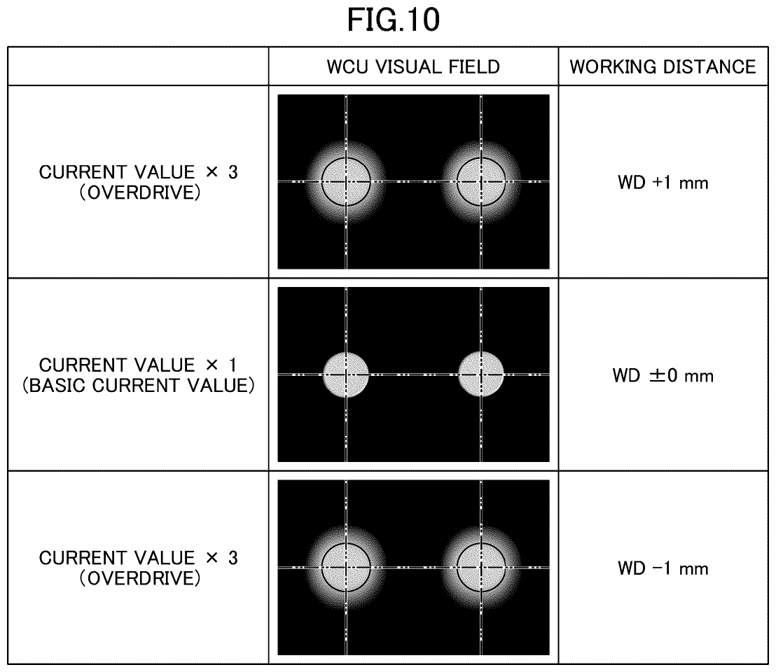

A method to compensate a contrast of the standard image and the measurement images in the present embodiment is described referring to FIG. 9 and FIG. 10.

When a distance between the probe camera unit 41 and the wafer camera unit 42 corresponds to the sum of their respective working distances WD1+WD2 (i.e. when the focal point FP1 of the probe camera unit 41 corresponds to the focal point FP2 of the wafer camera unit 42), a contrast of the optical dot pattern included in the measurement image is the highest. Conversely, when the focal point FP1 of the probe camera unit 41 does not correspond to the focal point FP2 of the wafer camera unit 42, a contrast of the optical dot pattern included in the measurement image is low.

FIG. 9 is a drawing illustrating one example of a relationship between a working distance and an optical dot pattern. As shown in FIG. 9, when the focal points correspond (the left of the figure), edges of the optical dots included in the measurement image are clear and the contrast is high. Conversely, when the stage 25 is raised from a situation in which focal points correspond, the working distance WD2 of the wafer camera unit 42 becomes shorter and the focal point FP1 falls outside the depth of field. In this case, the edges of the optical dots included in the measurement image are blurred and the contrast becomes lower (the center of the figure). Similarly, when the stage 25 is lowered from the situation in which focal points correspond, the working distance WD2 of the wafer camera unit 42 becomes longer and the focal point FP1 falls outside the depth of field. In this case, the edges of the optical dots included in the measurement image are also blurred and the contrast becomes lower (the right of the figure).

In the present embodiment, when the height of the stage 25 is varied from the situation in which focal points correspond, the brightness of the optical dot pattern is adjusted according to the variation of the height of the stage 25. When the contrast of the optical dot pattern included in the measurement image is low, if the brightness of the projected the optical dot pattern becomes higher, the edges of the optical dots become clearer and the contrast becomes higher.

FIG. 10 is a drawing illustrating one example of brightness adjustment according to a working distance. As shown in FIG. 10, the current value when the focal points correspond to the working distance (±0 mm) is referred to as the basic current value (×1); when the stage 25 is lowered and the working distance becomes longer (+1 mm), the current value is overdriven to 3 times of the basic current value. Similarly, when the stage 25 is raised and the working distance becomes shorter (−1 mm), the current value is overdriven to three times of the basic current value. In this case, it is preferable to adjust such that the larger the variation of the working distance (absolute value) is, the larger the magnification of overdrive is.

By adjusting the brightness of the optical dot pattern according to the variation of the height of the stage 25, measurement images of high contrast can be captured even while the stage 25 is raised or lowered. Moreover, by using the measurement image of high contrast, the position difference and the inclination difference of the stage 25 can be detected clearly.

### <Inclination Difference Detection>

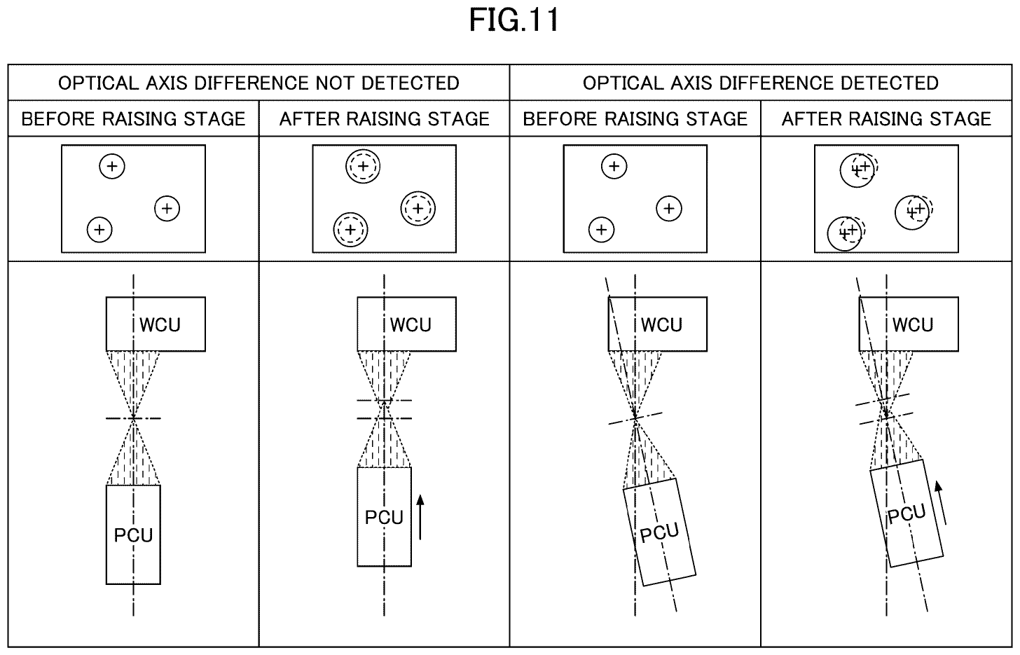

A method to detect an inclination difference in the present embodiment is described referring to FIG. 11. FIG. 11 is a drawing illustrating one example of a relationship between an optical axis difference and an optical dot pattern.

As shown in FIG. 11, when the optical axes projected by the probe camera unit 41 correspond to the optical axes received by the wafer camera unit 42 (optical axis difference not detected), the positions of the optical dots do not vary before or after raising the stage 25. Conversely, when the optical axes projected by the probe camera unit 41 do not correspond to the optical axes received by the wafer camera unit 42 (optical axis difference detected), the positions of the optical dots vary before or after raising the stage 25. Moreover, in FIG. 11, solid lines refer to the observed edges of each optical dot, dotted lines refer to the edges of each optical dot before raising the stage, and +marks refer to center positions of each optical dot.

The inclination detector 106 calculates, for example, a positional variation of each optical dot by comparing center positions of each optical dot in the measurement images captured before varying the height of the stage 25, and center positions of each optical dot in the measurement images captured after varying the height of the stage 25. The inclination detector 106 averages variations of the center positions of each optical dot, and detects the average as the inclination difference.

### <Distortion Compensation>

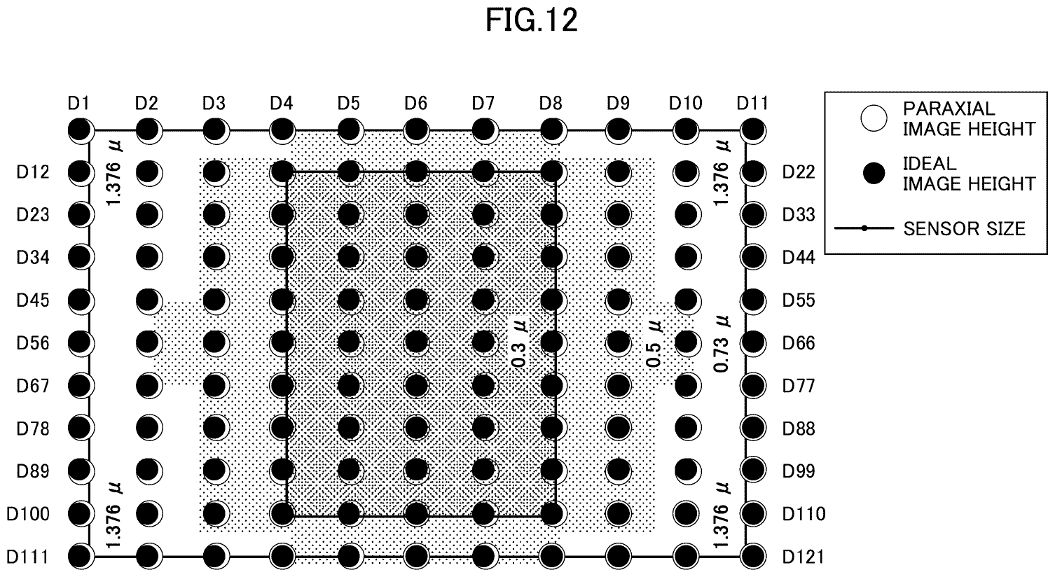

Distortion compensation of present the embodiment is described referring to FIG. 12. FIG. 12 is a drawing illustrating one example of distortion compensation.

In the inspection apparatus 10, as preheating and tests are performed at a high temperature, optical distortion may occur in the measurement images captured by the wafer camera unit 42. The optical distortion can be compensated by the following method.

FIG. 12 is a drawing illustrating one example of distortion compensation. In FIG. 12, ideal image heights correspond to the positions of the respective optical dots in the optical dot pattern projected by the probe camera unit 41, and paraxial image heights correspond to the positions of the respective optical dots captured in the measurement images.

The measurement image acquirer 104 compensates optical distortion according to the positions of each optical dot included in the measurement images. By using the measurement images with the compensated optical distortion, the position difference and the inclination difference of the stage 25 can be detected accurately.

### <Procedure>

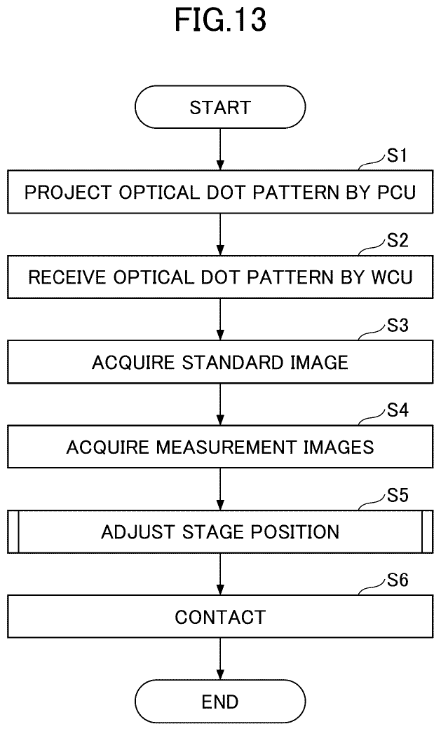

An inspection method performed by the inspection apparatus 10 in the present embodiment is described referring to FIG. 13. FIG. 13 is a flow chart illustrating one example of the inspection method.

In a step S1, the projection controller 101 of the controller 50 controls the probe camera unit 41 to project the optical dot pattern. The probe camera unit 41 projects the optical dot pattern where optical dots are arranged, according to the control by the controller 50, by the projector 61.

In a step S2, the light receiving controller 102 of the controller 50 controls the wafer camera unit 42 to receive the optical dot pattern projected by the probe camera unit 41. The wafer camera unit 42 starts to receive the optical dot pattern, according to the control by the controller 50.

In a step S3, the standard image acquirer 103 of the controller 50 controls the probe camera unit 41 to capture the standard image. The probe camera unit 41 captures the standard image including the optical dot pattern projected from the projector 61 by the camera 63, according to the control by the controller 50.

In a step S4, the measurement image acquirer 104 of the controller 50 controls the wafer camera unit 42 to capture the measurement images. The wafer camera unit 42 captures the measurement images including the optical dot pattern received by the wafer camera unit 42 by the camera 82, according to the control by the controller 50.

In a step S5, the controller 50 controls the actuator 23 to adjust the stage 25, according to the standard image captured in the step S3, and the measurement images captured in the step S4. Specifically, first, the position detector 105 detects a position difference, according to the standard image and the measurement images. The position detector 105 transmits the detected position difference to the stage adjuster 107. Subsequently, the inclination detector 106 detects the inclination difference, according to measurement: images. The inclination detector 106 transmits the detected inclination difference to the stage adjuster 107.

The stage 107 adjuster receives the position difference from the position detector 105. Subsequently, the stage adjuster 107 controls the actuator 23 to move the position of the stage 25 in the x-y plane in order to correct the position difference. Moreover, the stage adjuster 107 receives the inclination difference from the inclination detector 106. Additionally, the stage adjuster 107 controls the actuator 23 to vary the inclination of the stage 25 with respect to the z-axis in order to correct the inclination difference.

In a step S6, the stage adjuster 107 of the controller 50 controls the actuator 23 to bring the needle probe tips 38 into contact with the test pad, disposed on the wafer W, disposed on the stage 25. The stage adjuster 107 raises the stage 25, whose position has been adjusted in the step S5, to as high as the needle probe tips 38 to come in contact with each test pad on the wafer W.

When the needle probe tips 38 come in contact with each test pad on the wafer W, the controller 50 controls the external tester 31 to evaluate an electric characteristic of the wafer W. The controller 50 receives the evaluation result, evaluating the electric characteristic of the wafer W, from the external tester 31 and outputs the evaluation result.

### <Stage Adjustment Process>

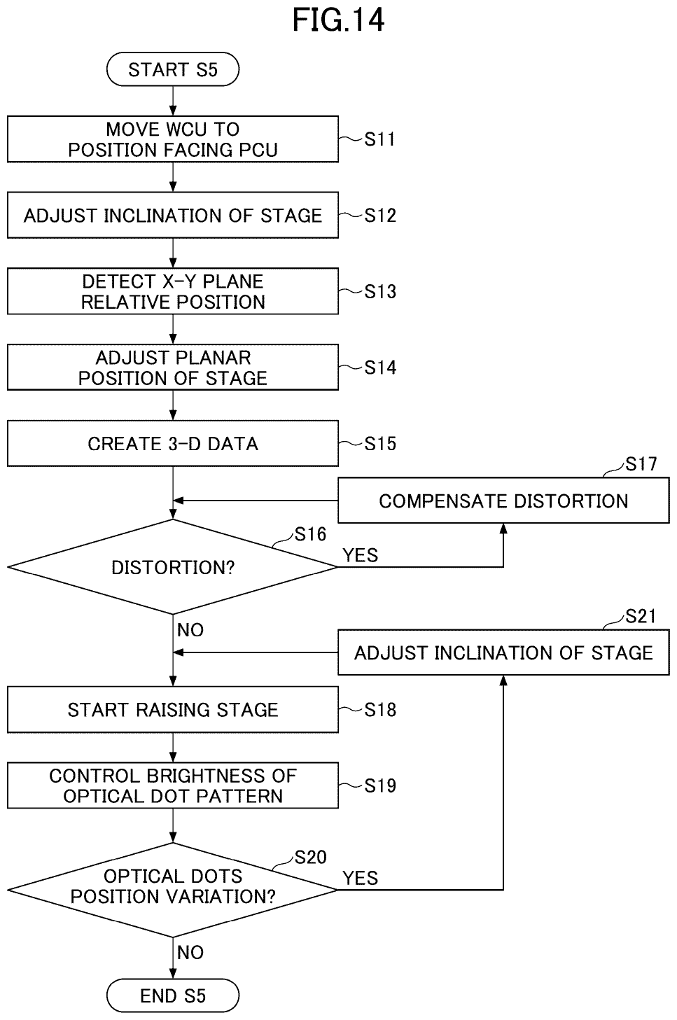

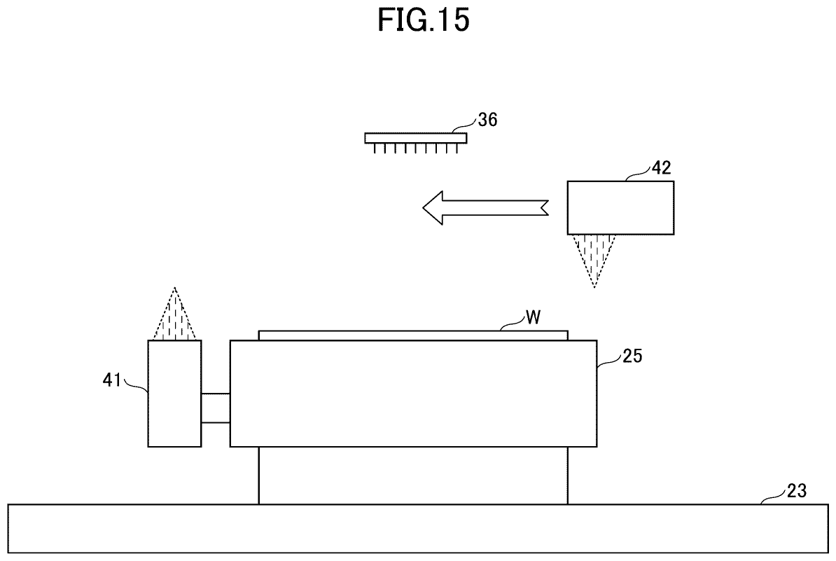

A stage adjustment process (a step S5 of FIG. 13) is described in more detail referring to FIG. 14 to FIG. 20. FIG. 14 is a flow chart illustrating one example of a stage adjusting process. FIG. 15 to FIG. 20 are schematic diagrams illustrating examples of conditions of the inspection apparatus.

In a step S11, the light receiving controller 102 moves the wafer camera unit 42 to a position facing the probe camera unit 41 in a spiral orbit. Moving the wafer camera unit 42 in a spiral orbit enables detecting the optical dot pattern more quickly. The light receiving controller 102 detects the optical dot pattern from the measurement images acquired by the measurement image acquirer 104, moving the wafer camera unit 42. When the optical dot pattern is detected from the measurement images, the light receiving controller 102 stops moving the wafer camera unit 42.

As shown in FIG. 15, the wafer camera unit 42 is disposed between the wafer W and the probe card 36. The wafer camera unit 42 moves towards a position facing the probe camera unit 41 disposed at the stage 25.

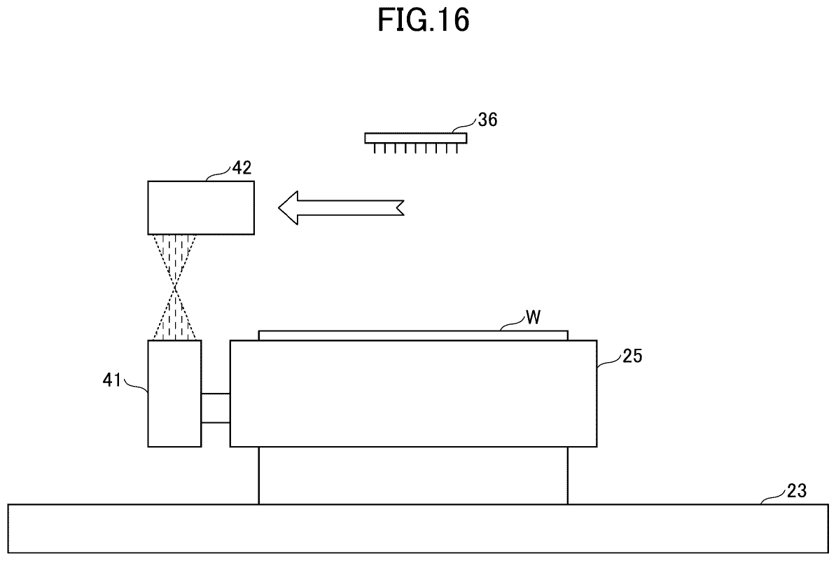

As shown in FIG. 16, the probe camera unit 41 projects the optical dot pattern upward along the spiral orbit. When the wafer camera unit 42 moves to a position facing the probe camera unit 41, the optical dot pattern projected by the probe camera unit 41 is incident on the wafer camera unit 42. The wafer camera unit 42 detects the optical dot pattern from the incident light.

Continuing description from FIG. 14, in a step S12, the stage adjuster 107 receives the measurement images from the measurement image acquirer 104. Subsequently, the stage adjuster 107 adjusts the inclination of the stage 25 according to sizes and contrasts of each optical dot included in the measurement images. When inclinations of the probe camera unit 41 and the wafer camera unit 42 are different, sizes and contrasts of each optical dot included in the measurement images are uneven. The stage adjuster 107 adjusts the inclination of the stage 25 in order for sizes and contrasts of each optical dot included in the measurement images to be even.

In a step S13, the position detector 105 receives the standard image from the standard image acquirer 103. Next, the position detector 105 receives measurement images from the measurement image acquirer 104. Subsequently, the position detector 105 detects the position difference according to the standard image and the measurement images. Specifically, the position detector 105 estimates a relative position of the measurement images in the standard image by template matching, and calculates a distance between the estimated relative position and the center position. The position detector 105 transmits the detected position difference to the stage adjuster 107.

In a step S14, the stage adjuster 107 receives the position difference from the position detector 105. Subsequently, the stage adjuster 107 adjusts the planar position of the stage 25 according to the position difference.

In a step S15, the controller 50 recognizes the center position of the wafer W by the wafer camera unit 42, and creates a three-dimensional data of the wafer W. Moreover, the controller 50 recognizes the center position of the probe card 36 by the probe camera unit 41, and creates a three-dimensional data of the probe card 36. The controller 50 can recognize a three-dimensional shape of the probe card 36 and the wafer W, according to the center position and the three-dimensional data of the probe card 36 and the wafer W, and bring the needle probe tips 38 into contact with the test pad on the wafer W more accurately.

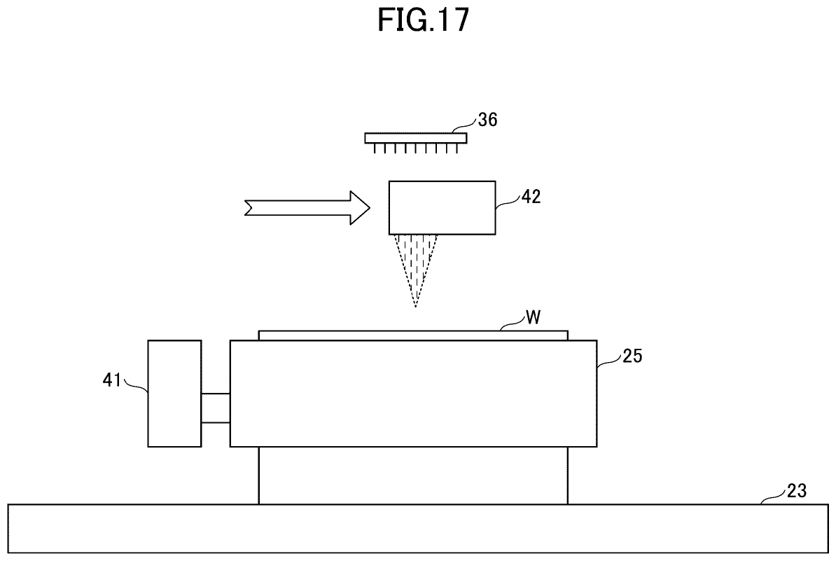

As shown in FIG. 17, the wafer camera unit 42 moves to the position facing the wafer W disposed on the stage 25, and recognizes the center position of the wafer W. The wafer camera unit 42 captures the wafer W at the position facing the wafer W. The controller 50 recognizes the center position of the wafer W, according to the image of the wafer W. Moreover, the controller 50 creates the three-dimensional data of the wafer W.

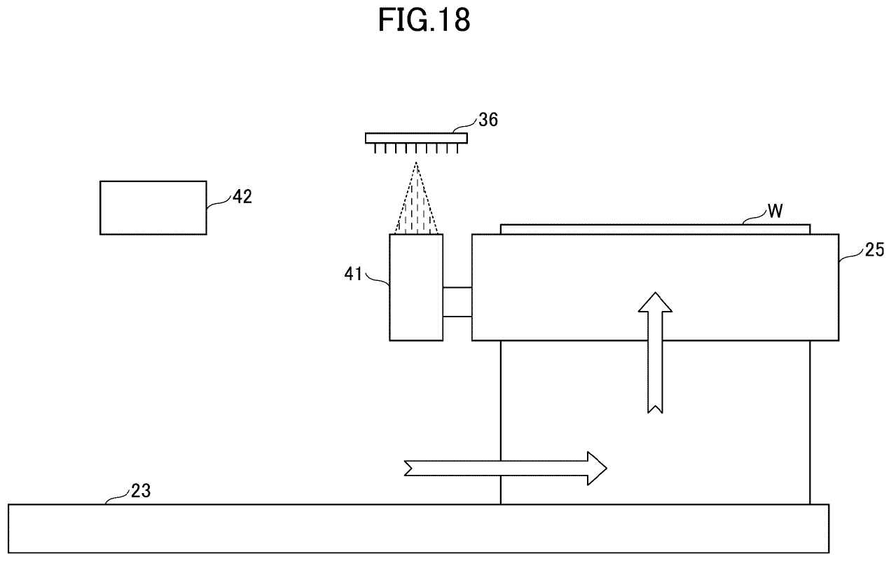

As shown in FIG. 18, the stage 25 moves to the position where the probe camera unit 41 and the probe card 36 are facing each other by the actuator 23, and starts to rise. The probe camera unit 41 captures the probe card 36 at the position facing the probe card 36, with the optical shutter 72 closed, using the projected optical dot pattern and the filter wheel 70. The controller 50 recognizes the center position of the probe card 36, according to the image of the probe card 36. Moreover, the controller 50 creates high-resolution three-dimensional data of the probe card 36.

Subsequently, the stage adjuster 107 moves the stage 25 to a position facing the probe card 36. Moreover, the light receiving controller 102 moves the wafer camera unit 42 to a position facing the probe camera unit 41.

Continuing description from FIG. 14, in a step S16, the measurement image acquirer 104 determines whether optical distortion occurs in the measurement images. The measurement image acquirer 104 can determine whether optical distortion occurs by detecting positions of respective optical dots included in the measurement images, and comparing the positions of the respective optical dots and the positions of the optical dots at the ideal image height.

When optical distortion occurs (YES), the measurement image acquirer 104 progresses the process to a step S17. Conversely, when optical distortion does not occur (NO), the measurement image acquirer 104 progresses the process to a step S18.

In the step S17, the measurement image acquirer 104 compensates the optical distortion of the measurement images. The measurement image acquirer 104 can compensate the optical distortion of the measurement images according to the difference between the positions of respective optical dots and the positions of the optical dots at the ideal image height.

Subsequently, the measurement image acquirer 104 returns the process to the step S16 and repeats the step S16 again. The measurement image acquirer 104 continues to compensate the optical distortion until the optical distortion is not detected in the measurement images.

In a step S18, the stage adjuster 107 starts raising the stage 25.

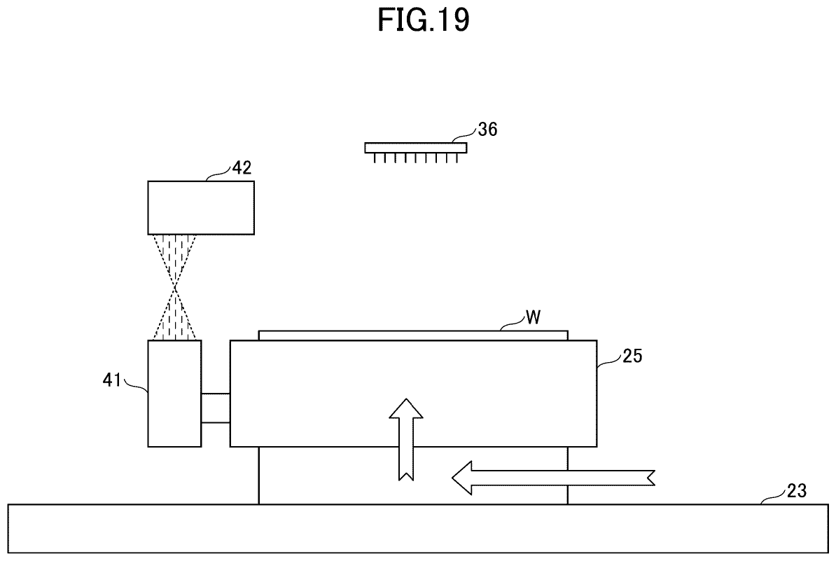

As shown in FIG. 19, the stage 25 starts rising by the actuator 23 at the position facing the probe card 36. The wafer camera unit 42 receives the optical dot pattern projected by the probe camera unit 41 at a position facing the probe camera unit 41. The probe camera unit 41 captures the measurement images at a predetermined interval.

Continuing description from FIG. 14, in a step S19, the stage adjuster 107 notifies the variation of height of the stage 25 to the projection controller 101. The projection controller 101 adjusts brightness of the optical dot pattern according to the variation of the height of the stage 25, and controls the probe camera unit 41 in order to project the optical dot pattern at the adjusted brightness. The probe camera unit 41 varies the brightness of the optical dot pattern according to the control by the controller 50.

In a step S20, the inclination detector 106 receives the measurement images from the measurement image acquirer 104. Subsequently, the inclination detector 106 detects the positional variations of the optical dots included in the measurement images captured before and after the height of the stage 25 varies.

Subsequently, the inclination detector 106 determines whether positional variations of the optical dots occur. When positional variations of the optical dots occur (YES), the inclination detector 106 progresses the process to a step S21. Conversely, when the positional variations of the optical dots do not occur (NO), the inclination detector 106 ends the stage adjusting processes.

In the step S21, the inclination detector 106 detects the inclination difference according to the positional variations of optical dots detected in the step S20. Specifically, the inclination detector 106 calculates the variations of the center position of respective optical dots included in the measurement images, and detects the average of the variations as the inclination difference. Subsequently, the inclination detector 106 transmits the inclination difference to the stage adjuster 107.

The stage adjuster 107 receives the inclination difference from the inclination detector 106. Subsequently, the stage adjuster 107 adjusts inclination of the stage 25 according to the inclination difference.

Subsequently, the controller 50 returns the process to the step S18 and repeats processes of the step S18 to the step S20. The controller 50 continues to adjust the inclination difference until positional variation of the optical dots accompanying the rising of the stage 25 does not occur.

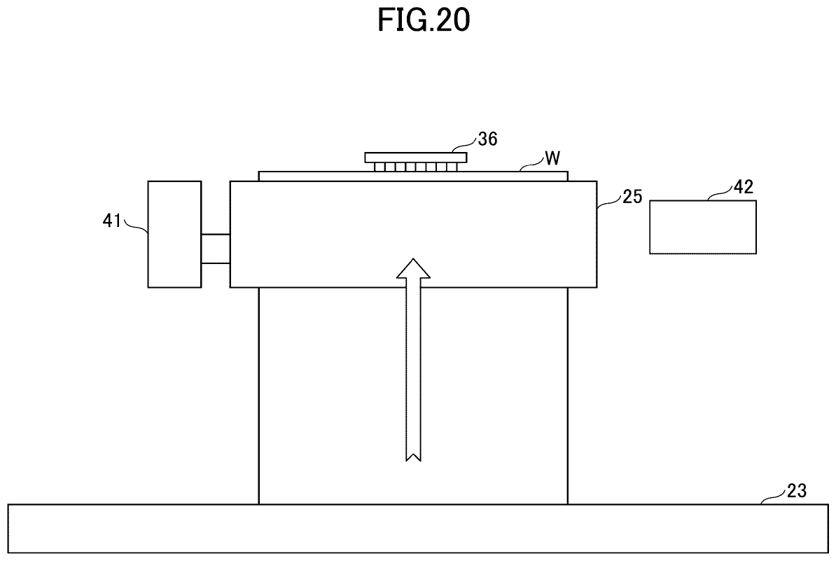

As shown in FIG. 20, the stage 25 continues to rise while the position difference and the inclination difference are adjusted. When the needle probe tips disposed on the probe card 36 come in contact with the test pad on the wafer W disposed on the upper surface of the stage 25, the stage 25 stops rising. The needle probe tips disposed on the probe card 36 come in contact with the test pad on the wafer W accurately.

### <Effects of the Embodiment>

An inspection apparatus 10 of the present embodiment projects an optical dot pattern where optical dots are arranged by a probe camera unit 41, receives the optical dot pattern by a wafer camera unit 42, and adjusts a stage 25 on which a wafer W is disposed, according to a standard image including the optical dot pattern projected by the probe camera unit 41, and measurement images including the optical dot pattern detected by the wafer camera unit 42, where at least two optical dots are included. The inspection apparatus 10 can detect position difference and inclination difference of the stage 25 accurately. According to one aspect, in the present embodiment, a needle tip of a probe can be brought into contact with an electrode of an inspection object accurately.

The inspection apparatus 10 of the present embodiment may capture measurement images at a positional relationship where the probe camera unit 41 and the wafer camera unit 42 are facing each other. In the present embodiment, the optical dot pattern projected by the probe camera unit 41 can be certainly detected by the wafer camera unit 42.

The inspection apparatus 10 of the present embodiment may capture measurement images with higher magnification than that of a standard image. The inspection apparatus 10 may adjust position of the stage 25 according to relative position of the measurement images with respect to the standard image. The inspection apparatus 10 may project the optical dot pattern of which the optical dots are arranged asymmetrically with respect to a predetermined axis. In the present embodiment, position difference of the stage 25 can be detected accurately.

The inspection apparatus 10 of the present embodiment may adjust an inclination of the stage 25 according to the positional variations of the optical dots included in the measurement images. In the inspection apparatus 10, the probe camera unit 41 is fixed to the stage 25, and when the height of the stage 25 varies, the measurement images are captured respectively. The inspection apparatus 10 may vary brightness of the optical dot pattern according to the variation of height of the stage 25. In the present embodiment, inclination difference of the stage 25 can be detected accurately.

### <Supplement>

The structure of the inspection apparatus 10 of the embodiment above is one example, and at least a part of processes performed by a controller 50 may be performed by another information processor connected to the controller 50 data-communicably. For example, another information processor connected to the controller 50 data-communicably may be a computer which provides cloud services.

According to one aspect, a needle tip of a probe can be brought into contact with an electrode of an inspection object accurately.

Further, the present invention is not limited to these embodiments, and various variations and modifications may be made without departing from the scope of the present invention.

What is claimed is:

1. An adjustment method for an inspection apparatus configured to inspect an inspection object by bringing a tip of a probe disposed on a probe card into contact with an electrode disposed on the inspection object, comprising:
projecting, by a projector, an optical dot pattern in which optical dots are arranged;
receiving the optical dots by a light receiver;
capturing a standard image including the optical dots projected by the projector;
capturing a measurement image including at least two of the optical dots of the optical dot pattern received by the light receiver; and
adjusting a stage on which the inspection object is disposed, according to the standard image and the measurement image.

2. The method according to claim 1, wherein the measurement image is captured at a positional relationship in which the projector faces the light receiver.

3. The method according to claim 1, wherein the measurement image is captured with higher magnification than the standard image.

4. The method according to claim 1, wherein during the adjusting, a position of the stage is adjusted according to a relative position of the measurement image with respect to the standard image.

5. The method according to claim 4, wherein in the optical dot pattern, the optical dots are arranged asymmetrically with respect to a predetermined axis.

6. The method according to claim 1, wherein during the adjusting, an inclination of the stage is adjusted according to positional variations of the optical dots included in the measurement images.

7. The inspection method according to claim 6, wherein the projector is fixed to the stage; and wherein when a vertical position of the stage varies, the measurement images are captured for respective vertical positions.

8. The inspection method according to claim 7, wherein the projector changes brightness of the optical dot pattern according to an amount of change in the vertical position of the stage.

9. An inspection apparatus for inspecting an inspection object by bringing a needle tip of a probe disposed on a probe card into contact with an electrode disposed on the inspection object, comprising:
a projector configured to project an optical dot pattern where optical dots are arranged;
a light receiver configured to receive the optical dot pattern;
a first camera configured to capture a standard image including the optical dot pattern projected by the projector;
a second camera configured to capture a measurement image including at least two of the optical dots of the optical dot patterns received by the light receiver; and
an adjuster configured to adjust a stage on which the inspection object is disposed, according to the standard image and the measurement image.

10. The inspection apparatus according to claim 9, wherein the second camera captures the measurement image with higher magnification than a magnification with which the first camera captures the standard image.
